(19) United States
(12) Patent Application Publication
(10) Pub. No.: US 2022/0328703 A1
(43) Pub. Date: Oct. 13, 2022

(54) PRINTABLE SOLAR SIGN

(71) Applicant: OptoGlo, Inc., Leominster, MA (US)

(72) Inventor: Kevin Donahue, Harvard, MA (US)

(73) Assignee: OptoGlo, Inc., Leominster, MA (US)

(21) Appl. No.: 17/718,214

(22) Filed: Apr. 11, 2022

Related U.S. Application Data
(60) Provisional application No. 63/173,798, filed on Apr. 12, 2021.

(51) Int. Cl. H01L 31/0232; H01L 31/0216; H01L 31/18

(52) U.S. Cl. CPC H01L 31/02325; H01L 31/02167; H01L 31/18

(57) ABSTRACT

The systems and methods of the present disclosure provide an opto-electronic print media. The opto-electronic print media can include a diffusion film having a printable surface and a second surface opposite the printable surface. The opto-electronic print media can include a light guide coupled to the second surface of the diffusion film. The opto-electronic print media can include a solar panel coupled to the light guide that captures light passing through the diffusion film and the light guide. The opto-electronic print media is feedable through a printer. The systems and methods of this present disclosure further provide a printable solar-powered sign. The printable solar powered sign can include a sheet structure. The sheet structure can include a diffusion film, a light guide, a solar panel, and a light source. The sheet structure can be passable through a printer such that the printer can print on the diffusion film.

### RELATED APPLICATIONS

This patent application claims the benefit of and priority to U.S. Provisional Patent Application No. 63/173,798 titled “PRINTABLE SOLAR SIGN,” and filed Apr. 12, 2021, the contents of all of which are hereby incorporated herein by reference in its entirety for all purposes

### BACKGROUND

Graphics can be illuminated by lighting sources. However, it can be challenging to properly illuminate graphics uniformly.

### SUMMARY

Conventional signs often require external light sources to be visible at night. Other implementations typically utilize an external solar panel, for example, a stop sign with a border composed of red light-emitting diodes and a post capped with a mounted solar panel. These signs are cumbersome, expensive and from and not aesthetically appropriate for all contexts. The systems and methods of this technical solution provide a self-contained, self-illuminating solar sign with an integrated solar panel, battery, and control electronics. The surface of the sign can include a diffusion film that appears white, but allows a large amount of light to pass through it and strike the surface of a solar panel embedded in the body of the sign. The surface of the sign can be print-ready, and the entire sign can be manufactured to be fed into a conventional printer, such as a large-format inkjet printer. Thus, the signs described herein can be self-illuminating sheets that are thin, for example, less than five millimeters thick.

At least one aspect of the present disclosure is directed to a printable solar-powered sign. The printable solar-powered sign can include a sheet structure. The sheet structure can include a diffusion film having a first printable surface and a second surface opposite the first surface. The sheet structure can include a light guide positioned in the housing and coupled to the second surface of the diffusion film. The light guide can evenly distribute light across the diffusion film to illuminate the first printable surface. The sheet structure can include a solar panel coupled to the light guide that captures light passing through the diffusion film and the light guide. The sheet structure can include a light source positioned adjacent to the light guide that receives stored electrical power from a battery electrically coupled to the solar panel. The sheet structure can have a profile passable through a printer such that the printer can print on the diffusion film.

In some implementations, the sheet structure includes the battery. In some implementations, the solar panel can charge the battery using a voltage generated based on the light passing through the diffusion film and the light guide. In some implementations, the printable solar sign includes a bracket that couples to a frame configured to position the printable solar-powered sign at a predetermined angle from a light source. In some implementations, the printable solar-powered sign includes a printable overlay film having a second printable surface coupled to the first printable surface of the diffusion film. In some implementations, the printable solar-powered sign includes a layer of latex ink disposed on the first printable surface.

In some implementations, the light guide includes a light guide surface having a plurality of light-extracting features formed thereon, the plurality of light-extracting features configured to evenly distribute the light across the diffusion film to illuminate the first printable surface.

In some implementations, the plurality of light-extracting features are located at predetermined positions that correspond to a design printed on the first printable surface of the diffusion film. In some implementations, the light source comprises one or more light-emitting diodes positioned at an edge of the light-guide. In some implementations, the printable solar-powered sign includes a controller and a voltage sensor electrically coupled to the solar panel. In some implementations, the controller monitors a voltage value from the voltage sensor and classifies the light passing through the diffusion film and the light guide produced by an external light source. In some implementations, the first printable surface of the diffusion film has greater than 70% angular diffusion. In some implementations, the diffusion film has a light transmission rate that exceeds 80%.

At least one other aspect of the present disclosure is directed to an opto-electronic print media. The opto-electronic print media can include a diffusion film having a printable surface and a second surface opposite the printable surface. The opto-electronic print media can include a light guide coupled to the second surface of the diffusion film. The opto-electronic print media can include a solar panel coupled to the light guide that captures light passing through the diffusion film and the light guide. The opto-electronic print media can be feedable through a printer.

In some implementations, the opto-electronic print media includes a battery electrically coupled to the solar panel. In some implementations, the solar panel can charge the battery using a voltage generated based on the light passing through the diffusion film and the light guide. In some implementations, the light guide includes a light guide surface having a plurality of light-extracting features formed thereon. In some implementations, the plurality of light-extracting features can evenly distribute the light across the diffusion film to illuminate the printable surface. In some implementations, the plurality of light-extracting features are located at predetermined positions on the light guide surface. In some implementations, the opto-electronic print media can include a light source position adjacent to the light guide that receives stored electrical power from a battery electrically coupled to the solar panel.

In some implementations, the light source includes one or more light-emitting diodes positioned at an edge of the light-guide. In some implementations, the opto-electronic print media can include a controller and a voltage sensor electrically coupled to the solar panel. In some implementations, the controller monitors a voltage value from the voltage sensor, and classifies the light passing through the diffusion film and the light guide produced by an external light source. In some implementations, the printable surface of the diffusion film has greater than 70% angular diffusion. In some implementations, the diffusion film has a light transmission rate that exceeds 80%.

Large signs are popular and ubiquitous. Such signs exist on billboards, sides of buildings and vehicles, including tractor trailers, buses, and trains. Most signs have a printed surface, often rendered by inkjet printers, including large-format printers that print a latex-based ink. Conventional printed signs are opaque, and cannot be seen at night. A small percentage of exterior signs are composed of LED Panels that present illuminated static images or even video. Other illuminated signs are composed of backlit panels that are powered by a connection to an electricity grid.

These and other aspects and implementations are discussed in detail below. The foregoing information and the following detailed description include illustrative examples of various aspects and implementations, and provide an overview or framework for understanding the nature and character of the claimed aspects and implementations. The drawings provide illustration and a further understanding of the various aspects and implementations, and are incorporated in and constitute a part of this specification. Aspects can be combined and it will be readily appreciated that features described in the context of one aspect of the invention can be combined with other aspects. Aspects can be implemented in any convenient form.

### BRIEF DESCRIPTION OF THE DRAWINGS

The accompanying drawings are not intended to be drawn to scale. Like reference numbers and designations in the various drawings indicate like elements. For purposes of clarity, not every component may be labeled in every drawing. The foregoing and other objects, aspects, features, and advantages of the disclosure will become more apparent and better understood by referring to the following description taken in conjunction with the accompanying drawings, in which:

FIG. 1A illustrates an exploded view of an example solar sign having a printable surface and a housing, in accordance with one or more implementations;

FIG. 1B illustrates a cross-sectional view of the example solar sign of FIG. 1A, in accordance with one or more implementations;

FIG. 2A illustrates an exploded view of an example printable solar sign sheet, in accordance with one or more implementations;

FIG. 2B illustrates a cross-sectional view of the example printable solar sign sheet shown in FIG. 2A, in accordance with one or more implementations;

FIG. 2C illustrates a front view of the example printable solar sign sheet shown in FIGS. 2A and 2B, in accordance with one or more implementations; and

FIG. 2D illustrates a side view of the example printable solar sign shown in FIGS. 2A, 2B, an 2C, in accordance with one or more implementations.

### DETAILED DESCRIPTION

The various concepts introduced above and discussed in greater detail below may be implemented in any of numerous ways, as the described concepts are not limited to any particular manner of implementation. Examples of specific implementations and applications are provided primarily for illustrative purposes.

Solar-powered illuminated signs are gaining popularity. In general, conventional signs can be used for traffic management and can include multiple externally-connected components. Common solar signs can include stop signs with a border composed of red light-emitting diodes and a post capped with a mounted solar panel. However, these signs are cumbersome, expensive and from a design standpoint, ugly. The techniques described in the present disclosure provide a printable sheet, with no external components. The sheet can be illuminated internally at night, or during dark conditions. The techniques described herein provide a thin (e.g., less than 5 mm thick, etc.) board with a print ready surface. The print-ready surface can be printed upon using a printer, such as an inkjet printer or a large-format latex inkjet printer.

The printable illuminated sign sheet described herein can include a stack of thin, functional layers. The layer exposed to an external can include a diffusion film with micron-scale surface features that facilitate extreme light turning or diffusion. As a result, the surface of the sheet can appear white, when in actuality the sheet can transmit more than 80% of the incident light into the underlying layers. Below the print-ready diffusion surface sits a thin light guide plate (LGP) that emits uniform lighting produced by light emission from edge mounted light sources, such as light-emitting diodes (LEDs). A solar panel or film can be coupled to the light guide plate, and can be electrically coupled to an electronics module. The electronics module can be in the sign sheet on same layer as, or on a layer proximate to, the solar panel or film in the light illuminated sign sheet.

Sunlight, or another external light, can traverse the diffusion surface of the printable layer and pass through the optically clear LGP and finally contact the underlying solar film or panel, which in turn generates electron flow. These electrons are subsequently forwarded to the internal battery to be stored as power for night illumination.

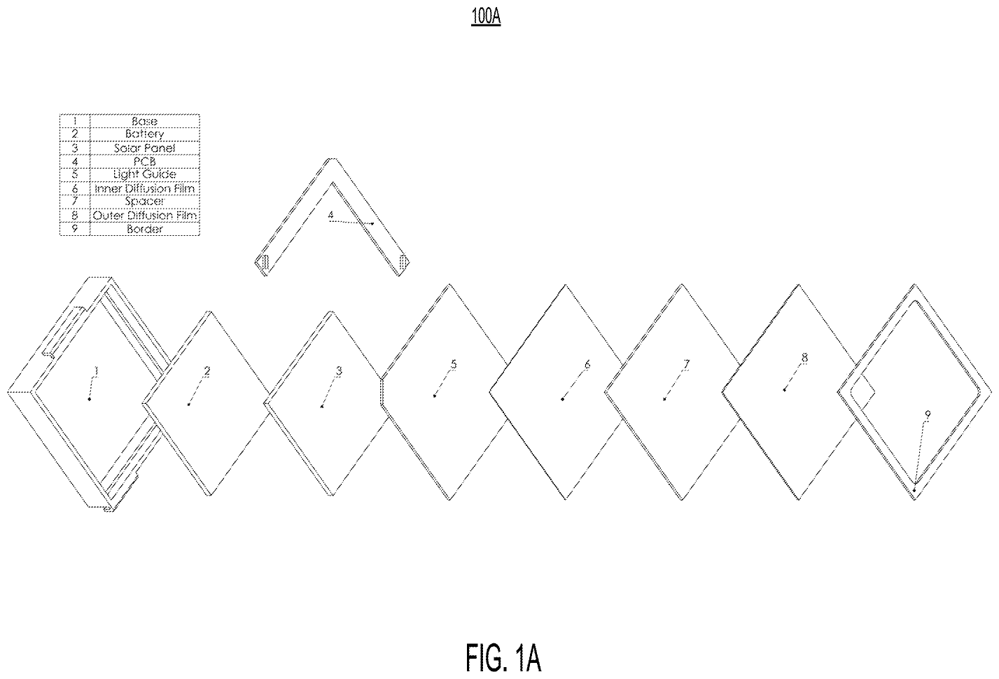

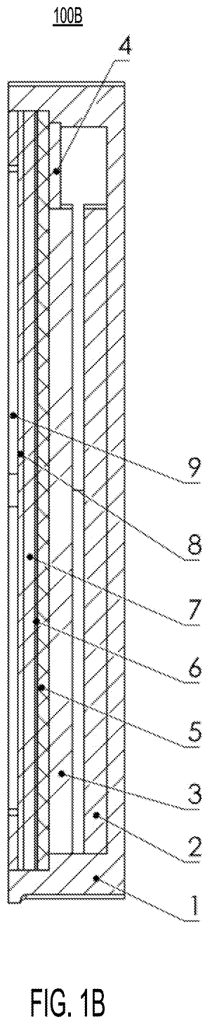

Referring now to FIG. 1A illustrated is an exploded view 100A of an example solar sign having a printable surface and a housing, in accordance with one or more implementations. The solar sign can include at least one base 1 (sometimes referred to as a “housing 1”), a battery 2, a solar panel 3, a printed circuit board (PCB) 4, a light guide 5, an inner diffusion film 6, a spacer 7, an outer diffusion film 8, and a border 9. As described herein, each of the components of the solar sign depicted in FIG. 1A can form a portion, or the entirety of, a layer of the solar sign. The layers can be stacked and coupled to one another, for example, using an adhesive or mechanical coupling or connector. In some implementations, the layers can be coupled to one another via mechanical force.

The base 1 can be a waterproof container that contains each of the layers depicted in FIG. 1A. The base 1 can prevent unwanted materials (e.g., water, dust, debris, etc.) from entering the sign and causing electrical issues or blocking light paths. The base 1 can be constructed from a polymer material, a metal material, or a composite material. As shown in the view 100A, each of the components of the solar sign (e.g., the battery 2, the solar panel 3, the printed circuit board (PCB) 4, the light guide 5, the inner diffusion film 6, the spacer 7, the outer diffusion film 8, the border 9, etc.) can be positioned in or coupled to the housing, for example, in one or more layers of a stack. The components can be coupled to one another, for example, by one or more mechanical features (e.g., each of the components can be manufactured to fit together tightly within the base 1, etc.), such as connectors, fasteners, or other mechanical coupling features. In some implementations, one or more of the components of the solar sign can be coupled to one another via an adhesive or other non-mechanical coupling agent. In some implementations, the adhesive can be an optically transparent adhesive. The outer portion of the base 1 can be coupled to the supporting hardware, such as an A-frame. In some implementations, the base 1 can include one or more connectors to couple to other solar signs or other support features.

The battery 2 can be a thin, flat battery that can provide electrical power to one or more of the electronic components of the solar sign, as described herein. The battery 2 can be a re-chargeable battery, such as a lithium-ion battery, a lithium-polymer battery, a nickel-cadmium battery, or another type of high-density re-chargeable battery with a thin form factor. The battery 2 can receive electric power from the solar panel 3, for example, via charging circuitry present on the PCB 4. The battery 2 can discharge electrical energy through one or more light sources, such as light-emitting diodes, that are present in the solar sign. In some implementations, the battery 2 can be positioned in the solar sign such that it is easily removable. In such implementations, the components of the solar sign can fit together such that the solar sign can be disassembled, and the battery 2 can be replaced.

The solar panel 3 can be coupled to the battery 2, and the light guide 5, and can absorb light that passes through the outer diffusion film 8, the spacer 7, and the inner diffusion film 6, and the light guide 5. The solar panel 3 can provide electric power to the other components of the solar sign described herein. Light emitted from an external light source (e.g., the sun, etc.) can pass through the layers of the diffusion film, the spacer, and the light guide 5, and contact the surface of the solar panel 3. Photons in the light can be absorbed by the solar panel 3 and converted into an electron flow that is stored in the battery 2 (e.g., via power circuitry on the PCB 4, etc.). The battery 2 can store a charge over the course of a day (e.g., via the solar panel 3 absorbing energy from an external light source, etc.). Then, in circumstances of low light (e.g., each evening if the solar sign is positioned outside, etc.), the solar panel 3 can generate a decreased electron flow (e.g., a decreased voltage from what was produced during periods of high external light, etc.) The solar panel 3 can be any sort of photovoltaic cell or photovoltaic film having a thin form factor. The solar panel 3 can be constructed from semiconducting materials, such as doped silicon.

The PCB 4 can include electronics, such as power electronics that can control the flow of electrons output by the solar panel 3. As described herein above, the PCB 4 can be electrically coupled to the solar panel 3 via one or more electrical connections (not shown). The PCB 4 can include one or more voltage sensors that can monitor voltage signals produced by the solar panel 3. In some implementations, the PCB 4 can include one or more voltage sensors that monitor the voltage level of the battery. For example, each of the voltage sensors can output a signal (e.g., an electrical signal, etc.) that indicates an amount of voltage generated by the solar panel 3 or the battery 2. The signals can be received, for example, by a controller on the PCB 4.

The PCB 4 can include one or more light sources that can illuminate the solar sign via the light guide 5 (described in further detail herein). The light sources can be any sort of light source that can emit light in response to receiving electric energy. The light sources can be electrically coupled to and receive electric power from the battery, for example, via power circuitry (e.g., voltage converters, etc.) on the PCB 4. The light sources can emit light with an intensity that is proportional to the amount of electric power received from the power circuitry. Thus, the power circuitry can control the amount of electric power provided to the light sources, and thus the amount of light emitted by the light sources. The light sources can have a thickness that corresponds (e.g., about equal to, less than, etc.) to a thickness of the light guide 5. The light sources can be, for example, one or more LEDs or any other type of light source. The light source can be a bright source of light that uses a low amount of power.

The PCB 4 can include a controller that can monitor voltage signals produced by the voltage sensors and provide power controls to the electronic components (e.g., the light sources, the solar panel 3, etc.) of the solar sign. The controller can include at least one processor and a memory (e.g., a processing circuit, etc.). The memory can store processor-executable instructions that, when executed by processor, cause the processor to perform one or more of the operations described herein. The processor can include a microprocessor, an application-specific integrated circuit (ASIC), a field-programmable gate array (FPGA), etc., or combinations thereof. The memory can include, but is not limited to, electronic, optical, magnetic, or any other storage or transmission device capable of providing the processor with program instructions. The memory can further include a memory chip, ASIC, FPGA, read-only memory (ROM), random-access memory (RAM), electrically erasable programmable ROM (EEPROM), erasable programmable ROM (EPROM), flash memory, optical media, or any other suitable memory from which the processor can read instructions. The instructions can include code from any suitable computer programming language.

The processor of the electronics module can receive signals (e.g., via an interconnect or other communications bus, etc.) from the voltage sensors on the PCB 4 that correspond to the amount of light being received by the solar panel 3. Based on the mount of light received from the solar panel 3, the processor can provide signals to one or more switches (e.g., transistors, integrated circuits, etc.) that cause the battery 2 to provide electric power to the light sources connected to the PCB 4. For example, if the processor detects that the amount of voltage produced by the solar panel 3 has fallen below a predetermined threshold, the processor can determine that the solar sign is not properly or completely illuminated. Based on the signals from the voltage sensors, the processor can determine whether the amount of light striking the solar panel 3 represents a temporary blockage (e.g., an external light source is obscured temporarily, etc.), of the amount of light striking the solar panel 3 represents that the solar sign is now in a dark environment (e.g., it is now night time, or the solar sign has been moved to a dark room, etc.). The processor can compensate for the low light levels by transitioning form an unilluminated (e.g., the light source is not receiving power, etc.) state to an illuminated (e.g., the light source is receiving power, etc.) state. The processor can provide (e.g., via the power circuitry, transistors, switches, etc.) an amount of power that is proportional to the amount of light required to illuminate the solar sign. In some implementations, the processor can store information about the amount and the color of one or more graphical designs or printed images printed on the outer surface of the outer diffusion film 8. For darker images with more ink, the processor can provide more electric power to the light sources, thus providing more light to illuminate the darker graphic. Likewise, if a graphic on the solar sign is absent, or has light or small amounts of ink, the processor can provide slightly less electric power to the, thus providing uniform illumination for the solar sign.

The light guide 5 can be positioned adjacent to the solar panel 3, such that light passing through the light guide can strike the solar panel 3 and generate electric power. The light guide 5 can be a transparent plate of material that can both receive and guide light from one or more light sources, such as the light sources on the PCB 4 or an external light source, such as the sun. As described herein, the surface of the light guide 5 (e.g., the surface coupled to the inner diffusion film 6, etc.) can include one or more light extraction features, such as lenses or lenslets. In some implementations, the surface of the light guide 5 opposite the surface coupled to the inner diffusion film 6 can include one or more light exaction features. The light extraction features can extract a portion of the light injected into the light guide 5, such as the light emitted by the light sources on the PCB 4. The light guide 5 can guide another portion of the light injected into the light guide towards an opposite edge of the light guide 5. The light extraction features can be precisely placed across the surface of the light guide 5 in a predetermined pattern, such that light is uniformly extracted, and thus emitted, across the entire surface of the light guide 5. Thus, the light guide 5 can uniformly illuminate the other layers of the solar sign (e.g., the inner diffusion film 6, the spacer 7, the outer diffusion film 8, etc.), including any graphical designed printed on the outer diffusion film.

The light guide 5 can be optically coupled to the light sources in the solar sign. In some implementations, the light sources can be positioned within a cavity formed in the light guide 5. The light source can emit light through the cavity and into the body of the light guide 5, thereby injecting light into the light guide 5. In some implementations, the light guide 5 does not include a cavity, and instead is a uniform rectangular plate that can receive light emitted from the light source via an edge of the light guide 5. In such implementations, the light sources can be positioned external to the light guide 5 and inject light into the light guide plate via the edge. The light guide 5 can have a shape that accommodates the light sources, for example, having one or more edges or corners that are “clipped” or removed from a uniform rectangular plate, as shown in FIG. 1A.

The inner diffusion film 6 can be a sheet of partially transparent film that has a first surface coupled to a spacer 7 (e.g., which can be a transparent plastic spacer, for example, to achieve a desired structural thickness, etc.) and a second surface that is coupled to the light guide 5. The inner diffusion film 6 can be a partially transparent film that appears white, or another solid color, while still allowing an amount of light to pass through the diffusion film and into the light guide 5. For example, light emitted by an external light source (e.g., the sun, etc.) can pass through both the outer diffusion film 8, the spacer 7, and the inner diffusion film 6, striking the solar panel 3 where it is absorbed. The inner diffusion film 6 can be uniformly illuminated by the light extracted by the light extraction features of light guide 5, such that the solar sign and any graphical designs printed thereon can be illuminated in low-light environments (e.g., at night time, etc.). In some implementations, the inner diffusion film 6 can have greater than 70% angular diffusion. In some implementations, the inner diffusion film 6 can have a light transmission rate that exceeds 80%. The inner diffusion film can aid in the operation of the light guide 5, which in some implementations can provide a more uniformly distributed light pattern when exposed to air. The inner diffusion film 6 can have a rough surface, and thus when coupled to the light guide 5, the majority of the surface of the light guide 5 is exposed directly to air, because the rough surface of the inner diffusion film 6 is not uniform or perfectly flat.

The spacer 7 can be a thin, flat portion of plastic that acts as a buffer between the inner diffusion film 6 and the outer diffusion film 8. The spacer 7 can be manufactured from a transparent material, such as glass, a transparent acrylic, or another type of transparent plastic. The spacer 7 can have similar dimensions to the inner diffusion film 6 and the outer diffusion film 8. The spacer 7 can have a thickness selected to allow each of the components of the solar sign to fit together in the base 1 of the solar sign. The spacer 7 can have high transmissivity, such that light easily passes through the spacer 7. The spacer 7 can allow light diffused from the inner diffusion film 6 to pass largely uninterrupted to the outer diffusion film 8, thereby illuminating the solar sign. Likewise, the spacer 7 can receive light from an external light source (e.g., the sun, etc.) via the outer diffusion film 8, and allow the light to pass largely uninterrupted through the inner diffusion film 6, striking the solar panel 3.

The outer diffusion film 8 can be a sheet of partially transparent film that has a first surface exposed to an external environment and a second surface that is coupled to the spacer 7. The outer diffusion film 8 can include a light-turning imprinted surface (e.g., the surface facing the external environment, etc.). The outer diffusion film 8 can include a partially transparent surface that appears white, or another solid color, while still allowing an amount of light to pass through the diffusion film and into the light guide 5. Light from an external light source (e.g., the sun, etc.) can pass through the outer diffusion film 8, the spacer 7, the inner diffusion film 6, and the light guide 5, striking the solar panel 3 where it is absorbed. The outer diffusion film 8 can be a printable film, such that the outer diffusion film 8 can be made from a material to which printer ink can be directly applied. Thus, in some implementations, the solar sign can be passed through a printer, such as a wide format inkjet printer, which can print ink directly onto the outer diffusion film 8 of the solar sign. The solar sign can be placed on or coupled to a template that guides the solar sign through the printer to facilitate the printing process.

The outer diffusion film 8 can be printed using a latex ink, a black ink, a white ink, or any other semi-transparent ink. The outer diffusion film 8 can be uniformly illuminated by the light extracted by the light extraction features of light guide 5, such that the solar sign and any graphical designs printed thereon can be illuminated in low-light environments (e.g., at night time, etc.). In some implementations, and as described herein above, the outer diffusion film 8 can be coupled to an overlay film such that the illuminated outer diffusion film 8 provides uniform illumination through the overlay film. In some implementations, the outer diffusion film 8 can be easily removable and replaceable from the base 1. Thus, different designs for the solar sign can easily be changed by exchanging the outer diffusion films 8 having graphical designs printed thereon.

The border 9 can provide a weather-proof border for the exposed edges of the solar sign, surrounding the outer diffusion film 8. As shown, the outer diffusion film 8 can be exposed to the external environment through the large opening in the border 9. The border 9 can be manufactured from a material similar to that used to manufacture the base 1. The border 9 can be coupled to the border 9 to create a weather-proof seal, thereby preventing water, dust, or other debris from interfering with the internals of the solar sign. In some implementations, the border 9 can be removable, such that the outer diffusion film 8 can be easily removed and replaced. This can allow for different designs to be displayed on the same sign by exchanging different outer diffusion films 8 having different designs printed thereon. In some implementations, the base 1 can include one or more brackets or connectors that couple the solar sign to a frame (not pictured). The frame can position the printable solar sign at a predetermined angle from a light source, such as the sun. In doing so, the frame can position the solar sign such that the sign appears flat to a viewer (e.g., completely upright), while still absorbing a large percentage of light emitted by an external light source.

Referring now to FIG. 1B, illustrated is a cross-sectional view 100B of the example solar sign shown in FIG. 1A, in accordance with one or more implementations. As shown in the view 100B, each of the layers in the solar sign can be pressed against one another firmly, such that they are fixed in place in the base 1 of the solar sign. Also as shown, each of the components can fit within the base 1 such that the components are coupled to the base 1, for example, via mechanical or frictional force. In some implementations, an adhesive can be disposed between one or more of the layers of the solar sign. In some implementations, the adhesive can be an optically transparent adhesive with a similar index of refraction to other components of the solar sign (e.g., the light guide 5, etc.). Each of the components of the solar sign can be placed in the base in a particular order. As shown, the base 1 can form a housing for the sign, and can include one or more attachment or guiding features (e.g., grooves, slots, etc.) into which the other components of the solar sign can fit or connect.

The battery 2 can first be positioned near the bottom of the base 1. In some implementations, the battery 2 can fit into one or more slots, grooves, or recessed portions of the base 1. Next, the solar panel 3 can be positioned top of, or adjacent to, the battery 2. The solar panel 3 can be electrically coupled to the battery 2. The PCB 4 can then be positioned in the base 1 adjacent to the solar panel. The PCB 4 can be positioned such that any light sources present on the PCB 4 will be aligned with the light guide 5 when the light guide 5 is positioned in the solar sign. The light guide 5 can be positioned on top of the solar panel 3, such that light passing through the light guide 5 from an external light source can be passed to the surface of the solar panel 3. Further, the light guide 5 can be positioned in the base 1 such that an edge of the light guide 5 can receive light from a light source, such as a light source positioned on or electrically coupled to the PCB 4. In some implementations, the light source can be electrically coupled to but physically separate from the PCB 4 (e.g., on a separate circuit board module, etc.).

The inner diffusion film 6 can be positioned on top of the light guide 5, such that the light emitted from the light sources and extracted by the light extraction features on the surface of the light guide 5 is diffused through the inner diffusion film, thereby evenly illuminating the solar sign. The spacer 7 can be positioned on top of the inner diffusion film 6. As shown, the spacer can provide additional depth to the stack of functional components of the solar sign, and provide a buffer through which light from the outer diffusion film 8 can pass before reaching the inner diffusion film 6. The outer diffusion film 8 can be positioned on top of the spacer 7. As described herein above, the outer diffusion film 8 can include a printable surface exposed to the external environment. Inks such as latex inks, or other types of inks, can be printed directly onto the printable surface of the outer diffusion film 8. Finally, the border 9 can create a seal between the outer diffusion film 8 and the base 1, thereby creating a weather-proof, printable sign. It should be understood that the various signs described herein can be scaled to any appropriate dimension, and the entire sign as pictured in FIGS. 1A and 1B can have a profile passable through a printer such that the printer can print on the outer diffusion film 8.

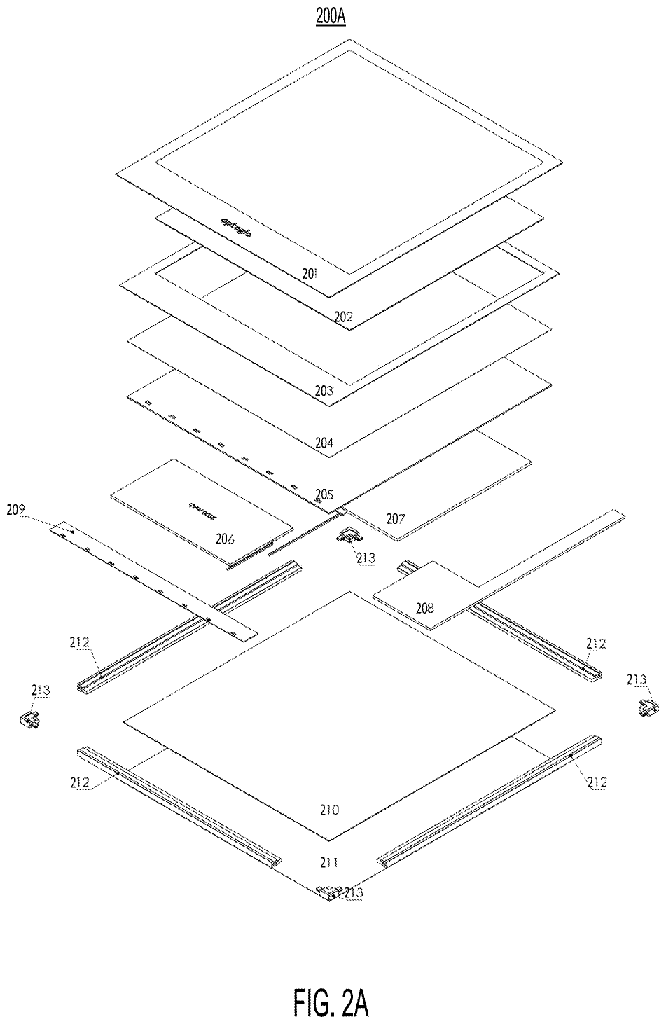

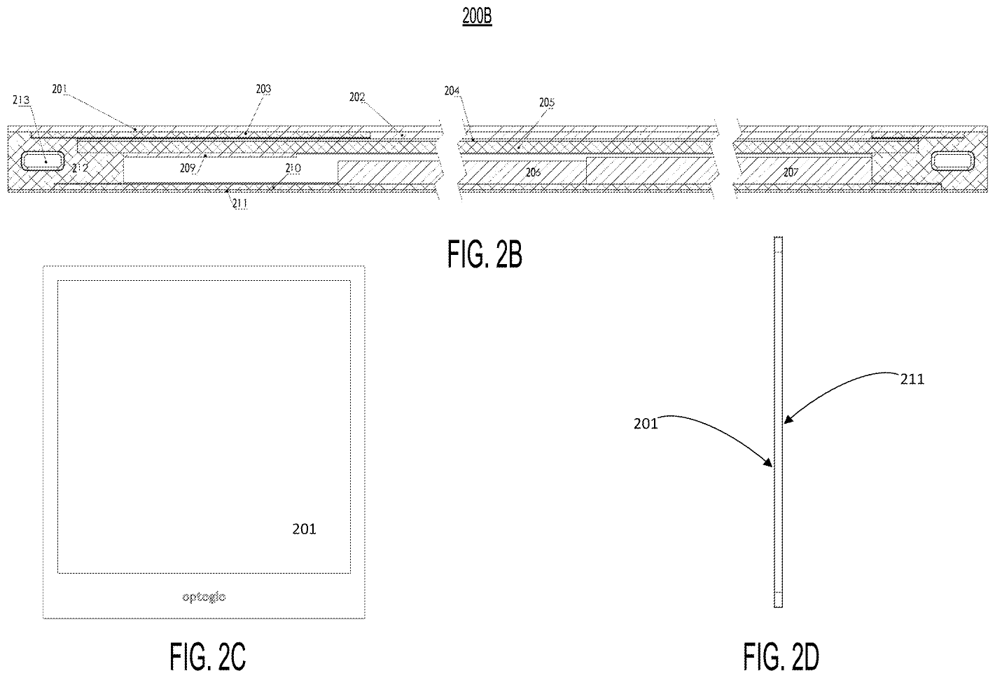

Referring now to FIG. 2A, illustrated is an exploded view 200A of an example printable solar sign sheet, in accordance with one or more implementations. The solar sign sheet shown in FIG. 2A can be a stack of functional materials, similar to the printable solar sign depicted in FIGS. 1A and 1B. The printable solar sign shown in the view 200A can include a top diffusion film 201, a spacer 202, a border 203, an inner diffusion film 204, a light guide 205, a battery 206, a solar panel 207, a filler 208, a PCB 209, a back plate 210, vinyl 211, a rail 212, and a corner piece 213. As described herein, each of the components of the solar sign depicted in FIG. 2A can form a portion, or the entirety of, a layer of the printable solar sign. The components can be coupled together, for example, via an adhesive or mechanical connectors, to form a sheet of layered, functional components. In some implementations, the layers can be coupled to one another via mechanical force such as friction.

The printable solar sign, including all of the components outlined above, can have a sheet structure that is thin, for example, less than five millimeters thick. The solar sign can be fed into a printer, for example, a wide format inkjet printer. Some examples of wide-format inkjet printers include the HP R1000 or the HP R2000 large-format latex inkjet printer. Said printers can print latex ink on the surface of the top diffusion film 201, thereby creating a design on the sign that can be illuminated in low-light environments. The design can be printed using a latex ink. Thus, the solar sign described herein can be an opto-electronic print media.

Starting from the bottom of the stack of functional components, the corner piece 13 and the rails 212 can form portions of the edges of the solar sign. The corner piece can include one or more pegs, or other types of connectors, that allow the corner piece 213 to be connected to two of the rails 212. Four corner pieces 13 can be used in conjunction with four rails 212 to define the edges of the solar sign. The corner pieces 13 and the rails 212 can be formed from any suitable material, for example, a polymer material, a metal material, or a composite material. In some implementations, the rails can be formed from aluminum or steel. In some implementations, the corner pieces 13 and the rails 212 can include one or more grooves, slots, or recesses into which one or more of the components of the solar sign can rest or be coupled. In some implementations, the rails 212 and the corner pieces can couple to the back plate 210. The vinyl 211 can be a sheet of vinyl that covers the back portion of the rails 212, the corner pieces 213, and the back plate 210, creating a weather-proof seal across the bottom of the solar sign. The back plate 210 can be a rigid plate onto which the other layers of the solar sign are stacked or coupled. The back plate 210 can be formed from any suitable material, including plastics, metals, or composite materials.

The battery 206, the solar panel 207, the filler 208, and the PCB 209 can together form the next layer of the solar sign. The battery 206 can be similar to and include any of the structure of functionality of the battery 2 described herein above in connection with FIGS. 1A and 1B. The battery 206 can be a thin, flat battery that can provide electrical power to one or more of the electronic components of the solar sign, as described herein. The battery 206 can be a re-chargeable battery, such as a lithium-ion battery, a lithium-polymer battery, a nickel-cadmium battery, or another type of high-density re-chargeable battery with a thin form factor. In some implementations, the battery 206 can be less than about 3 millimeters thick. The battery 206 can receive electric power from the solar panel 207, for example, via charging circuitry present on the PCB 209. The battery 206 can discharge electrical energy through one or more light sources, such as light-emitting diodes, that are present in the solar sign. In some implementations, the battery 206 can be positioned in the solar sign such that it is easily removable. In such implementations, the components of the solar sign can fit together such that the solar sign can be disassembled, and the battery 206 can be replaced.

Likewise, the solar panel 207 can be similar to and include any of the structure and functionality of the solar panel 3 described herein above in connection with FIGS. 1A and 1B. The solar panel 207 can be coupled to the battery 2, and the light guide 205, and can absorb light that passes through the outer diffusion film 8, the spacer 7, and the inner diffusion film 6, and the light guide 205. The solar panel 207 can provide electric power to the other components of the solar sign described herein. Light emitted from an external light source (e.g., the sun, etc.) can pass through the layers of the diffusion film, the spacer, and the light guide 205, and contact the surface of the solar panel 207. Photons in the light can be absorbed by the solar panel 207 and converted into an electron flow that is stored in the battery 206 (e.g., via power circuitry on the PCB 4, etc.). The battery 2 can store a charge over the course of a day (e.g., via the solar panel 207 absorbing energy from an external light source, etc.). Then, in circumstances of low light (e.g., each evening if the solar sign is positioned outside, etc.), the solar panel 207 can generate a decreased electron flow (e.g., a decreased voltage from what was produced during periods of high external light, etc.) The solar panel 207 can be any sort of photovoltaic cell or photovoltaic film having a thin form factor. The solar panel 207 can be constructed from semiconducting materials, such as doped silicon.

The PCB 209 can be similar to and include any of the structure and functionality of the PCB 209 described herein in connection with FIGS. 1A and 1B. The PCB 209 can include electronics, such as power electronics that can control the flow of electrons output by the solar panel 207. As described herein above, the PCB 209 can be electrically coupled to the solar panel 207 via one or more electrical connections (not shown). The PCB 209 can include one or more voltage sensors that can monitor voltage signals produced by the solar panel 207. In some implementations, the PCB 209 can include one or more voltage sensors that monitor the voltage level of the battery 206. For example, each of the voltage sensors can output a signal (e.g., an electrical signal, etc.) that indicates an amount of voltage generated by the solar panel 207 or the battery 206. The signals can be received, for example, by a controller on the PCB 209.

The PCB 209 can include one or more light sources that can illuminate the solar sign via the light guide 205 (described in further detail herein). In some implementations, the one or more light sources can be physically separate from but still electrically coupled to the PCB 209, and any components thereof (e.g., the processor, power electronics, switches, etc.). The light sources can be any sort of light source that can emit light in response to receiving electric energy. The light sources can be electrically coupled to and receive electric power from the battery, for example, via power circuitry (e.g., voltage converters, etc.) on the PCB 209. The light sources can emit light with an intensity that is proportional to the amount of electric power received from the power circuitry. Thus, the power circuitry can control the amount of electric power provided to the light sources, and thus the amount of light emitted by the light sources. The light sources can have a thickness that corresponds (e.g., about equal to, less than, etc.) to a thickness of the light guide 205. The light sources can be, for example, one or more LEDs or any other type of light source. The light source can be a bright source of light that uses a low amount of power.

In some implementations, the PCB 209 can include one or more magnetic sensors. The magnetic sensors can be electrically coupled to one or more components of the PCB 209 (e.g., the processor, the power circuitry, etc.). The magnetic sensors can provide a signal to the components of the PCB 209 in response to sensing a magnetic field, for example, from a magnet positioned on a frame configured to hold the solar sign. The signal from the magnetic sensor can enable the use of the solar sign. Said another way, the solar sign can be used in connection with authorized frames that have magnets appropriately positioned to activate the magnetic sensors of the PCB 209. Once activated, the magnetic sensors can provide a signal that allows the sign to operate as intended (e.g., absorb light from the sun to charge the battery 206, and illuminate the sign in low-light environments, etc.). In some implementations, an electromagnetic sensor can be electrically coupled to the PCB 209. The electromagnetic radiation sensor can detect electromagnetic radiation emitted, for example, by an overlay film (e.g., similar to the top diffusion film 201, etc.) having an electromagnetic radiation source positioned thereon. Similar to the operation of the magnetic sensor, the electromagnetic radiation sensor can detect electromagnetic radiation from authorized overlay films. The electromagnetic radiation sensor can produce a signal that activates the other components of the PCB 209, allowing the solar sign to operate as intended, in response to detecting an electromagnetic radiation signal from an authorized solar sign. Such electromagnetic radiation signals can include, for example, a near-filed communication (NFC) signal, a Bluetooth signal, or any other type of electromagnetic radiation signal. The overlay film can be an optically clear sheet of film, and can include a printed surface. The overlay film can be positioned over the external surface of the top diffusion film 201.

The PCB 209 can include a controller that can monitor voltage signals produced by the voltage sensors and provide power controls to the electronic components (e.g., the light sources, the solar panel 207, etc.) of the solar sign. The controller can include at least one processor and a memory (e.g., a processing circuit, etc.). The memory can store processor-executable instructions that, when executed by processor, cause the processor to perform one or more of the operations described herein. The processor can include a microprocessor, an application-specific integrated circuit (ASIC), a field-programmable gate array (FPGA), etc., or combinations thereof. The memory can include, but is not limited to, electronic, optical, magnetic, or any other storage or transmission device capable of providing the processor with program instructions. The memory can further include a memory chip, ASIC, FPGA, read-only memory (ROM), random-access memory (RAM), electrically erasable programmable ROM (EEPROM), erasable programmable ROM (EPROM), flash memory, optical media, or any other suitable memory from which the processor can read instructions. The instructions can include code from any suitable computer programming language.

The processor of the electronics module can receive signals (e.g., via an interconnect or other communications bus, etc.) from the voltage sensors on the PCB 209 that correspond to the amount of light being received by the solar panel 207. Based on the mount of light received from the solar panel 207, the processor can provide signals to one or more switches (e.g., transistors, integrated circuits, etc.) that cause the battery 206 to provide electric power to the light sources connected to the PCB 209. For example, if the processor detects that the amount of voltage produced by the solar panel 207 has fallen below a predetermined threshold, the processor can determine that the solar sign is not properly or completely illuminated. Based on the signals from the voltage sensors, the processor can determine whether the amount of light striking the solar panel 207 represents a temporary blockage (e.g., an external light source is obscured temporarily, etc.), of the amount of light striking the solar panel 207 represents that the solar sign is now in a dark environment (e.g., it is now night time, or the solar sign has been moved to a dark room, etc.). The processor can compensate for the low light levels by transitioning form an unilluminated (e.g., the light source is not receiving power, etc.) state to an illuminated (e.g., the light source is receiving power, etc.) state. The processor can provide (e.g., via the power circuitry, transistors, switches, etc.) an amount of power that is proportional to the amount of light required to illuminate the solar sign. In some implementations, the processor can store information about the amount and the color of one or more graphical designs or printed images printed on the outer surface of the outer diffusion film 8. For darker images with more ink, the processor can provide more electric power to the light sources, thus providing more light to illuminate the darker graphic. Likewise, if a graphic on the solar sign is absent, or has light or small amounts of ink, the processor can provide slightly less electric power to the, thus providing uniform illumination for the solar sign.

The filler 208 can fill the empty space between the other components in the layer formed by the battery 206, the solar panel 207, and the PCB 209. As shown, each of the battery 206, the solar panel 207, and the PCB 209 can be sized such that each has a similar thickness, and fit together on a single layer or plane. However, in some cases, additional space between the battery 206, the solar panel 207, the PCB 209, and the edges of the sheet (e.g., defined by the rails 212 or other edge pieces (not pictured), etc.). The filler 208 can be sized to fill in the gaps formed between the battery 206, the solar panel 207, and the PCB 209 to complete a flat structural layer on top of the back plate 210. The filler 208 can be formed from any suitable non-conductive material, such as plastic, foam, or any other type of filler material. The filler 208 can have substantially similar (e.g., plus or minus 10%) thickness to the battery 206, the solar panel 207, and the PCB 209. Thus, the filler 208 can be used to form a complete layer with the battery 206, the solar panel 207, and the PCB 209 across the entire back plate 210. In some implementations, in addition or as a part of the filler 208, a board with cutouts to hold components, including the PCB 209 (e.g., and any electronics forming a part of the PCB 209, etc.). The board can be manufactured from any suitable material, such as a corrugated plastic material. The board can have a surface color that is similar to the surface color of the solar panel 207. In some implementations, an additional colored film can be positioned on this layer above the PCB 209, the battery 206, or the filler 208, or any combination thereof. The colored film can have a similar color to that of the solar panel 207.

The next layer in the stack can be formed from the light guide 205. The light guide 205 can be similar to and include any of the functional or structural features of the light guide 205 described herein in connection with FIGS. 1A and 1B. The light guide 205 can be positioned adjacent to the solar panel 207, such that light passing through the light guide 205 can strike the solar panel 207 and generate electric power. The light guide 205 can be a transparent plate of material that can both receive and guide light from one or more light sources, such as the light sources on the PCB 209 or an external light source, such as the sun. As described herein, the surface of the light guide 205 (e.g., the surface coupled to the inner diffusion film 204, etc.) can include one or more light extraction features, such as lenses or lenslets. In some implementations, the surface of the light guide 205 opposite the surface coupled to the inner diffusion film 204 can include one or more light exaction features. The light extraction features can extract a portion of the light injected into the light guide 205, such as the light emitted by the light sources on the PCB 209. The light guide 205 can guide another portion of the light injected into the light guide towards an opposite edge of the light guide 205. The light extraction features can be precisely placed across the surface of the light guide 205 in a predetermined pattern, such that light is uniformly extracted, and thus emitted, across the entire surface of the light guide 205. Thus, the light guide 205 can uniformly illuminate the other layers of the solar sign (e.g., the inner diffusion film 204, the top diffusion film 201, etc.), including any graphical designed printed on the outer diffusion film.

The light guide 205 can be optically coupled to the light sources in the solar sign. In some implementations, the light sources can be positioned within a cavity formed in the light guide 205. In some implementations, the cavity can be a hole in the light guide 205 into which the one or more light sources are inserted. The light source can have a thickness that is similar to or less than the thickness of the light guide 205. The light source can emit light through the cavity and into the body of the light guide 205, thereby injecting light into the light guide 205. In some implementations, the light guide 205 does not include a cavity, and instead is a uniform rectangular plate that can receive light emitted from the light source via an edge of the light guide 205. In such implementations, the light sources can be positioned external to the light guide 205 and inject light into the light guide plate via the edge.

The next layer in the solar sign can be formed from the inner diffusion film 204. The inner diffusion film 204 can be similar to and include any of the functional and structural features of the inner diffusion film 6 described herein in connection with FIGS. 1A and 1B. The inner diffusion film 204 can be a sheet of partially transparent film that has a first surface coupled to a border 203 and the spacer 202 (e.g., which can be a transparent plastic spacer, for example, to achieve a desired structural thickness, etc.), and a second surface that is coupled to the light guide 205. The inner diffusion film 204 can be a partially transparent film that appears white, or another solid color, while still allowing an amount of light to pass through the diffusion film and into the light guide 205. For example, light emitted by an external light source (e.g., the sun, etc.) can pass through both the top diffusion film 201, the spacer 202, and the inner diffusion film 204, striking the solar panel 207 where it is absorbed. The inner diffusion film 204 can be uniformly illuminated by the light extracted by the light extraction features of light guide 205, such that the solar sign and any graphical designs printed thereon can be illuminated in low-light environments (e.g., at night time, etc.). In some implementations, the inner diffusion film 204 can have greater than 70% angular diffusion. In some implementations, the inner diffusion film 204 can have a light transmission rate that exceeds 80%. The inner diffusion film can aid in the operation of the light guide 205, which in some implementations can provide a more uniformly distributed light pattern when exposed to air. The inner diffusion film 204 can have a rough surface, and thus when coupled to the light guide 205, the majority of the surface of the light guide 205 is exposed directly to air, because the rough surface of the inner diffusion film 204 is not uniform or perfectly flat.

The next layer in the solar sign can be formed from the border 203 and the spacer 202. The border 203 can provide a weather-proof border for the exposed edges of the solar sign, while surrounding the spacer 202. The spacer 202 can be positioned in the large opening of the border 203, and the spacer 202 and the border 203 can each be coupled to the inner diffusion film 204, described herein above. The border 203 can be manufactured from any suitable material, such as a plastic, rubber, metal, or composite material. In some implementations, the border 203 can be opaque. The spacer 202 can be a thin, flat portion of plastic that acts as a buffer between the inner diffusion film 204 and the top diffusion film 201. The spacer 202 can be manufactured from a transparent material, such as glass, a transparent acrylic, or another type of transparent plastic. The spacer 202 can have dimensions smaller than the inner diffusion film 204, such that the spacer 202 can fit snugly in the large opening of the border 203. Together, the spacer 202 and the border 203 can form a single layer having similar dimensions to the light guide 205. The spacer 202 can have a thickness similar to the thickness of the border 203. The spacer 202 can have high transmissivity, such that light easily passes through the spacer 202. The spacer 202 can allow light diffused from the inner diffusion film 204 to pass largely uninterrupted to the top diffusion film 201, thereby illuminating the solar sign. Likewise, the spacer 202 can receive light from an external light source (e.g., the sun, etc.) via the top diffusion film 201, and allow the light to pass largely uninterrupted through the inner diffusion film 204, striking the solar panel 207.

The top layer of the printable solar sheet can be formed from the top diffusion film 201. The top diffusion film 201 can include any of the functional or structural features of the outer diffusion film 8 described herein in connection with FIGS. 1A and 1B. The top diffusion film 201 can be a sheet of partially transparent film that has a first surface exposed to an external environment and a second surface that is coupled to the spacer 202 and the border 203. The top diffusion film 201 can include a light-turning imprinted surface (e.g., the surface facing the external environment, etc.). The top diffusion film 201 can include a partially transparent surface that appears white, or another solid color, while still allowing an amount of light to pass through the diffusion film and into the light guide 205. Light from an external light source (e.g., the sun, etc.) can pass through the top diffusion film 201, the spacer 202, the inner diffusion film 204, and the light guide 205, striking the solar panel 207 where it is absorbed. The top diffusion film 201 can be a printable film. The top diffusion film 201 can be made from a material to which printer ink can be directly applied. Thus, in some implementations, the solar sign (e.g., including the stack of one or more of the layers shown in FIG. 2A, etc.) can be passed through a printer, such as a wide format inkjet printer, which can print ink directly onto the top diffusion film 201 of the solar sign. The solar sign can be placed on or coupled to a template that guides the solar sign through the printer to facilitate the printing process.

The top diffusion film 201 can be printed on using a latex ink, a colored latex ink, a black ink, a white ink, or any other semi-transparent ink. The top diffusion film 201 can be uniformly illuminated by the light extracted by the light extraction features of light guide 205, such that the solar sign and any graphical designs printed thereon can be illuminated in low-light environments (e.g., at night time, etc.). In some implementations, and as described herein above, the top diffusion film 201 can be coupled to an overlay film such that the illuminated top diffusion film 201 provides uniform illumination through the overlay film. In some implementations, the top diffusion film 201 can be easily removable and replaceable. Thus, different designs for the solar sign can easily be changed by exchanging the top diffusion films 201 having different designs printed thereon.

Referring now to FIG. 2B, illustrated is a cross-sectional view 200B of the example printable solar sign sheet of FIG. 2A, in accordance with one or more implementations. As shown in the view 200B, each of the layers in the solar sign can be pressed against one another firmly, such that they are fixed in place in the base 1 of the solar sign. Also as shown, each of the components can fit within a housing or sheet structure, formed from the rails 212 (e.g., defining the edges of the sheet, etc.), the corner pieces 213 (e.g., defining the corners of the sheet, etc.), and the back plate 210 (e.g., forming the back of the sheet). To enhance weather-proofing and aesthetic appearance, a sheet of the vinyl 211 can cover any gaps formed between the corner pieces 213, the rails 212, and the back plate 210.

The components forming the layers of the solar sign can sit within the base formed from the back plate 210, the rails 212, and the corner pieces 213. In some implementations, an adhesive can be disposed between one or more of the layers of the solar sign. In some implementations, the adhesive can be an optically transparent adhesive with a similar index of refraction to other components of the solar sign (e.g., the light guide 205, etc.). Each of the components of the solar sign can be placed in the base in a particular order. As shown, the base can form a housing for the sign. In some implementations, the base can include one or more attachment or guiding features (e.g., grooves, slots, etc.) into which the other components of the solar sign can fit or connect.

The battery 206, the solar panel 207, the PCB 209, and the filler 208 (not pictured) can first be positioned near the bottom of the base, and can form the first layer of the printable solar sign. In some implementations, the battery 206 can fit into one or more slots, grooves, or recessed portions of the solar sign. The solar panel 207 and the PCB 209 can be positioned adjacent to the battery 206 such that the battery 206, the solar panel 207, the PCB 209, and the filler 208 (not pictured) form a single layer having a relatively uniform thickness across the entire surface of the back plate 210. The PCB 209 can be positioned such that any light sources present on the PCB 209 will be aligned with the light guide 205 when the light guide 205 is positioned in the solar sign. The light guide 205 can be positioned on top of the first layer formed from the battery 206, the solar panel 207, the PCB 209, and the filler 208 in the solar sign. Light passing through the light guide 205 from an external light source can be passed to the surface of the solar panel 207. Further, the light guide 205 can be positioned in the solar sign such that a portion of the light guide 205 can receive light from a light source, such as a light source positioned on or electrically coupled to the PCB 209. In some implementations, the light source can be electrically coupled to but physically separate from the PCB 209 (e.g., on a separate circuit board module, etc.).

The inner diffusion film 204 can be positioned on top of the light guide 205, such that the light emitted from the light sources and extracted by the light extraction features on the surface of the light guide 205 is diffused through the inner diffusion film 204, thereby evenly illuminating the solar sign. The spacer 202 and the border 203 form another internal layer on top of the inner diffusion film 204. As shown, the spacer 202 can have a similar thickness to the border 203, and provide a buffer through which light from the top diffusion film 201 can pass before reaching the inner diffusion film 204. The final layer formed from the top diffusion film 201 can be positioned on top of the layer formed from the spacer 202 and the border 203. As described herein above, the top diffusion film 201 can include a printable surface exposed to the external environment. Inks such as latex inks, or other types of inks, can be printed directly onto the printable surface of the top diffusion film 201. In some implementations, the top diffusion film 201 can create weather-proof seal between the border 203 and the top diffusion film 201, thereby creating a weather-proof, printable sign. It should be understood that the various signs described herein can be scaled to any appropriate dimension, and the entire sign as pictured in FIGS. 2A and 2B can have a profile passable through a printer such that the printer can print on the top diffusion film 201.

Referring briefly now to FIG. 2C, illustrated is a front view of the example printable solar sign sheet shown in FIGS. 2A and 2B, in accordance with one or more implementations. As shown, when fully assembled, the solar sign can resemble a regular sign. Graphical designs can be printed directly onto the surface of the top diffusion film 201, and the area in the center portion (e.g., within the region defined by the opening in the border, etc.) can be illuminated in low-light conditions. The solar sign can be thin enough to be used directly as a print media. FIG. 2D illustrates a side view of the example printable solar sign, showing that the sign itself, when assembled, can be thin enough to be fed directly into a printer. Thus, the solar signs here can be used directly as an opto-electronic print media that is self-contained, weather-proof, and includes automatic control circuitry that controls sign illumination and charging. In some implementations, one or more brackets (not pictured) can be coupled to or form a part of the back plate 210, the rails 212, or the corner pieces 213. The brackets can allow the sign to be mounted to one or more frames, such as an A-frame, that allows the sign to be positioned at an angle that appears upright, but is at a slight angle to absorb optimal amounts of light from external light sources.

While operations are depicted in the drawings in a particular order, such operations are not required to be performed in the particular order shown or in sequential order, and all illustrated operations are not required to be performed. Actions described herein can be performed in a different order.

The separation of various system components does not require separation in all implementations, and the described program components can be included in a single hardware or software product.

Having now described some illustrative implementations, it is apparent that the foregoing is illustrative and not limiting, having been presented by way of example. In particular, although many of the examples presented herein involve specific combinations of method acts or system elements, those acts and those elements may be combined in other ways to accomplish the same objectives. Acts, elements, and features discussed in connection with one implementation are not intended to be excluded from a similar role in other implementations.

The phraseology and terminology used herein is for the purpose of description and should not be regarded as limiting. The use of “including”, “comprising”, “having”, “containing”, “involving”, “characterized by”, “characterized in that”, and variations thereof herein is meant to encompass the items listed thereafter, equivalents thereof, and additional items, as well as alternate implementations consisting of the items listed thereafter exclusively. In one implementation, the systems and methods described herein consist of one, each combination of more than one, or all of the described elements, acts, or components.

As used herein, the terms “about” and “substantially” will be understood by persons of ordinary skill in the art and will vary to some extent depending upon the context in which they are used. If there are uses of the term which are not clear to persons of ordinary skill in the art given the context in which it is used, “about” will mean up to plus or minus 10% of the particular term.

Any references to implementations or elements or acts of the systems and methods herein referred to in the singular may also embrace implementations including a plurality of these elements, and any references in plural to any implementation or element or act herein may also embrace implementations including only a single element. References in the singular or plural form are not intended to limit the presently disclosed systems or methods, their components, acts, or elements to single or plural configurations. References to any act or element being based on any information, act, or element may include implementations where the act or element is based at least in part on any information, act, or element.

Any implementation disclosed herein may be combined with any other implementation or embodiment, and references to “an implementation,” “some implementations,” “one implementation,” or the like are not necessarily mutually exclusive and are intended to indicate that a particular feature, structure, or characteristic described in connection with the implementation may be included in at least one implementation or embodiment. Such terms as used herein are not necessarily all referring to the same implementation. Any implementation may be combined with any other implementation, inclusively or exclusively, in any manner consistent with the aspects and implementations disclosed herein.

The indefinite articles “a” and “an,” as used herein in the specification and in the claims, unless clearly indicated to the contrary, should be understood to mean “at least one.”

References to “or” may be construed as inclusive so that any terms described using “or” may indicate any of a single, more than one, and all the described terms. For example, a reference to “at least one of ‘A’ and ‘B’” can include only ‘A’, only ‘B’, as well as both ‘A’ and ‘B’. Such references used in conjunction with “comprising” or other open terminology can include additional items.

Where technical features in the drawings, detailed description, or any claim are followed by reference signs, the reference signs have been included to increase the intelligibility of the drawings, detailed description, and claims. Accordingly, neither the reference signs nor their absence has any limiting effect on the scope of any claim elements.

The systems and methods described herein may be embodied in other specific forms without departing from the characteristics thereof. The foregoing implementations are illustrative rather than limiting of the described systems and methods. Scope of the systems and methods described herein is thus indicated by the appended claims, rather than the foregoing description, and changes that come within the meaning and range of equivalency of the claims are embraced therein.

What is claimed is:

1. A printable solar-powered sign, comprising:
a sheet structure comprising:
a diffusion film having a first printable surface and a second surface opposite the first surface;
a light guide positioned in the housing and coupled to the second surface of the diffusion film, the light guide configured to evenly distribute light across the diffusion film to illuminate the first printable surface;
a solar panel coupled to the light guide that captures light passing through the diffusion film and the light guide; and
a light source positioned adjacent to the light guide that receives stored electrical power from a battery electrically coupled to the solar panel,
wherein the sheet structure has a profile passable through a printer such that the printer can print on the diffusion film.

2. The printable solar-powered sign of claim 1, wherein the sheet structure further comprises the battery, and wherein the solar panel is configured to charge the battery using a voltage generated based on the light passing through the diffusion film and the light guide.

3. The printable solar-powered sign of claim 1, further comprising a bracket that couples to a frame configured to position the printable solar-powered sign at a predetermined angle from a light source.

4. The printable solar-powered sign of claim 1, further comprising a printable overlay film having a second printable surface coupled to the first printable surface of the diffusion film.

5. The printable solar-powered sign of claim 1, further comprising a layer of latex ink disposed on the first printable surface.

6. The printable solar-powered sign of claim 1, wherein the light guide further comprises a light guide surface having a plurality of light-extracting features formed thereon, the plurality of light-extracting features configured to evenly distribute the light across the diffusion film to illuminate the first printable surface.

7. The printable solar-powered sign of claim 1, wherein the plurality of light-extracting features are located at predetermined positions that correspond to a design printed on the first printable surface of the diffusion film.

8. The printable solar-powered sign of claim 1, wherein the light source comprises one or more light-emitting diodes positioned at an edge of the light-guide.

10. The printable solar-powered sign of claim 1, further comprising a controller and a voltage sensor electrically coupled to the solar panel, wherein the controller monitors a voltage value from the voltage sensor, and classifies the light passing through the diffusion film and the light guide produced by an external light source.

11. The printable solar-powered sign of claim 1, wherein the first printable surface of the diffusion film has greater than 70% angular diffusion.

12. The printable solar-powered sign of claim 1, wherein the diffusion film has a light transmission rate that exceeds 80%.

13. An opto-electronic print media, comprising:
a diffusion film having a printable surface and a second surface opposite the printable surface;
a light guide coupled to the second surface of the diffusion film; and
a solar panel coupled to the light guide that captures light passing through the diffusion film and the light guide,
wherein the opto-electronic print media is feedable through a printer.

14. The opto-electronic print media of claim 13, further comprising a battery electrically coupled to the solar panel, and wherein the solar panel is configured to charge the battery using a voltage generated based on the light passing through the diffusion film and the light guide.

15. The opto-electronic print media of claim 13, wherein the light guide further comprises a light guide surface having a plurality of light-extracting features formed thereon, the plurality of light-extracting features configured to evenly distribute the light across the diffusion film to illuminate the printable surface.

16. The opto-electronic print media of claim 13, wherein the plurality of light-extracting features are located at predetermined positions on the light guide surface.

17. The opto-electronic print media of claim 13, further comprising a light source position adjacent to the light guide that receives stored electrical power from a battery electrically coupled to the solar panel.

18. The opto-electronic print media of claim 17, wherein the light source comprises one or more light-emitting diodes positioned at an edge of the light-guide.

18. The opto-electronic print media of claim 13, further comprising a controller and a voltage sensor electrically coupled to the solar panel, wherein the controller monitors a voltage value from the voltage sensor, and classifies the light passing through the diffusion film and the light guide produced by an external light source.

19. The opto-electronic print media of claim 13, wherein the printable surface of the diffusion film has greater than 70% angular diffusion.

20. The opto-electronic print media of claim 13, wherein the diffusion film has a light transmission rate that exceeds 80%.
